(19) United States
(12) Patent Application Publication
(10) Pub. No.: US 2009/0016038 A1
(43) Pub. Date: Jan. 15, 2009

(54) MATRIX RELAY

(75) Inventors: Tatsuo Shinoura, Kyoto (JP); Ryuichi Sato, Kyoto (JP); Takeo Okuda, Kyoto (JP)

Correspondence Address: OSHA LIANG L.L.P., TWO HOUSTON CENTER, 909 FANNIN, SUITE 3500, HOUSTON, TX, 77010, US

(73) Assignee: OMRON CORPORATION, Kyoto (JP)

(21) Appl. No.: 12/280,653

(22) PCT Filed: Mar. 12, 2007
(86) PCT No.: PCT/JP2007/054826

§ 371 Date: Aug. 25, 2008

(30) Foreign Application Priority Data
Mar. 14, 2006 (JP) 2006-069427

(51) Int. Cl. H05K 7/18

(52) U.S. Cl. 361/813

(57) ABSTRACT

To provide a matrix relay which has excellent extensibility that can easily change the number of contact circuits as required, a small number of components to be inventory-controlled, a small number of assembling processes and is highly productive. Therefore, there is provided a matrix relay wherein row leads 11-14 of a lead frame, which are wired so that a plurality of input terminals and a plurality of output terminals are disposed respectively at opposite both sides, column leads 21-24 of the lead frame, which are wired so that a plurality of input terminals and a plurality of output terminals are disposed respectively at both sides adjacent both the opposite sides, and a plurality of opening/closing elements 51-54, 61-64, 71-74, 81-84, which are respectively connected to the row leads 11-14 and the column leads 21-24, are encapsulated with a resin in a square housing. In particular, the row leads 11-14 are each formed with relay leads 25, 26 and three jumper lines 27-29.

### TECHNICAL FIELD

The present invention relates to a matrix relay, in particular to a matrix relay having excellent extensibility and high productivity.

### BACKGROUND ART

Conventionally, as a matrix relay, for example, there is one wherein yokes 3, in each of which a plurality of iron cores 2 are integrally vertically provided at predetermined intervals, are embedded in a base 1 at predetermined intervals to construct a number of relays, which are connected to one another (refer to Patent Document 1).

### Patent Document 1: JP8-250005A

### DISCLOSURE OF INVENTION

### Problems to be Solved by the Invention

However, in the above matrix relay, for example, when trying to change the number of contact circuits, it is required to change a design of a component such as the yoke 3 and thus its extensibility is low. Further, in a case where it is necessary to manufacture matrix relays with different numbers of contact circuits, it is required that components such as the yokes 3 with different outer dimensions be in stock, so that inventory control requires a lot of time and effort. Further, in the above matrix relay, it is required to successively assemble components such as the yokes 3 to the base 1, and thus there is a problem that the number of assembling processes is large and the productivity is low.

In view of the above problems, it is an object of the present invention to provide a matrix relay having excellent extensibility that is capable of easily changing the number of contact circuits as required, a small number of components to be inventory-controlled, a small number of assembling processes and high productivity.

### Means of Solving the Problems

In order to solve the above problems, in a matrix relay of the present invention, row leads of a lead frame, which are wired so that a plurality of input terminals and a plurality of output terminals are disposed respectively at opposite both sides, column leads of the lead frame, which are wired so that a plurality of input terminals and a plurality of output terminals are disposed respectively at both sides adjacent both the opposite sides, and a plurality of opening/closing elements, which are respectively connected to the row leads and the column leads, are encapsulated with a resin in a square housing; at least one of the row leads and the column leads is formed through at least one jumper line.

### EFFECT OF THE INVENTION

According to the present invention, by changing the shape of the leads of the lead frame and appropriately selecting the jumper lines, a matrix relay which can easily change the number of contact circuits and having excellent extensibility is obtained. Further, unlike the prior art example, it is not required that a large number of components with different outer dimensions be in stock, which facilitates inventory control. Furthermore, since the opening/closing elements are assembled in advance, a matrix relay having a small number of assembling processes and high productivity is obtained.

In an embodiment of the present invention, an intermediate region of each of the row leads or each of the column leads may be formed of a relay lead disposed in the lead frame and the jumper line.

According to the present embodiment, it becomes much easier to perform wiring through the relay leads, so that a degree of design freedom is enhanced.

In another embodiment of the present invention, the jumper line may be obtained by providing a bar-shaped conductive wire with steps on each of which a die pad is provided protrusively.

According to the present embodiment, if the die pads that are necessary are provided on desired positions of the jumper line, a matrix relay in which wiring work is facilitated is obtained.

### BRIEF DESCRIPTION OF DRAWINGS

FIG. 1A is a perspective view showing a first embodiment of a matrix relay of the present invention, and FIG. 1B a plan view showing an electrical wiring thereof;

FIG. 2 is a perspective view showing a case where a housing of the matrix relay of FIG. 1A is removed;

FIG. 3 is an exploded perspective view showing a case where the housing of the matrix relay of FIG. 1A is removed;

FIG. 4 is a perspective view showing a surface of a lead frame of the first embodiment;

FIG. 5 is a perspective view of the surface of the lead frame showing a state in which opening/closing elements are mounted;

FIG. 6 is a perspective view showing a rear surface of the lead frame of the first embodiment;

FIG. 7 is a perspective view of the rear surface of the lead frame showing a state in which opening/closing elements are mounted;

FIG. 8 is a perspective view showing a second embodiment of the matrix relay of the present invention;

FIG. 9 is a perspective view showing a case where a housing of the matrix relay shown in FIG. 8 is removed;

FIG. 10 is an exploded perspective view showing a case where the housing of the matrix relay shown in FIG. 8 is removed;

FIG. 11 is a perspective view showing a surface of a lead frame of the second embodiment;

FIG. 12 is a perspective view of the surface of the lead frame showing a state in which opening/closing elements are mounted; and

FIG. 13 is a plan view showing a rear surface of the lead frame of the second embodiment.

### DESCRIPTION OF NUMERALS

1: matrix relay
2: housing
10: lead frame
11-14: row leads
21-24: column leads
25, 26: relay leads
27-29: jumper lines
40-49: control leads
51-54: opening/closing elements
61-64: opening/closing elements
71-74: opening/closing elements
81-84: opening/closing elements
90: jumper lines
91-94: jumper lines
91a-91h: die pads
92a-92h: die pads
93a-93h: die pads
94a-94h: die pads

### BEST MODE FOR CARRYING OUT THE INVENTION

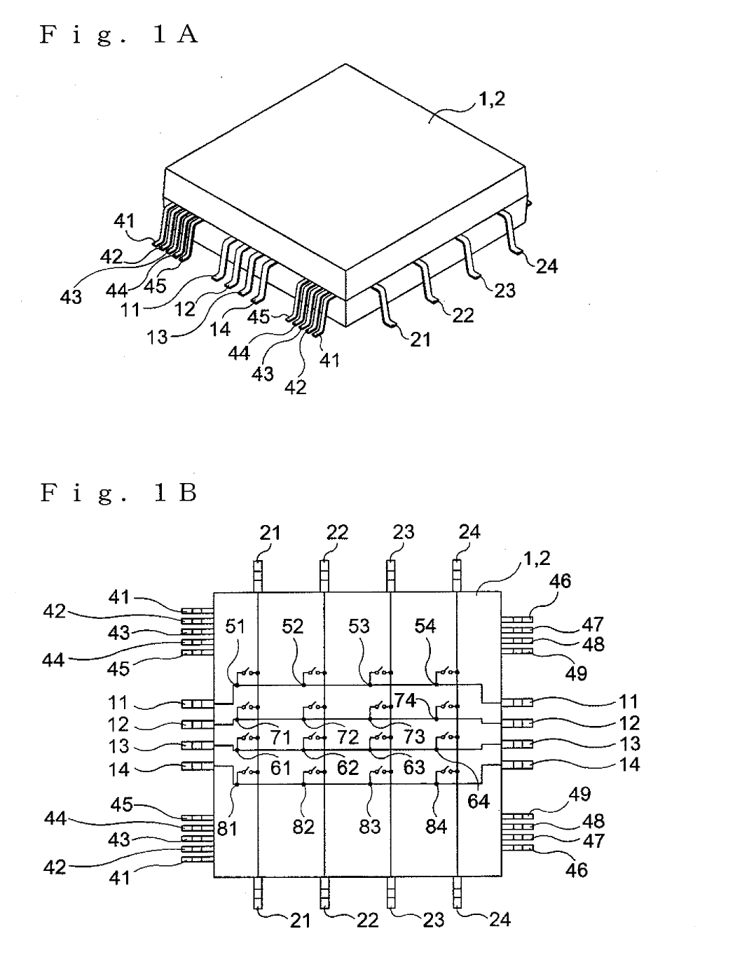

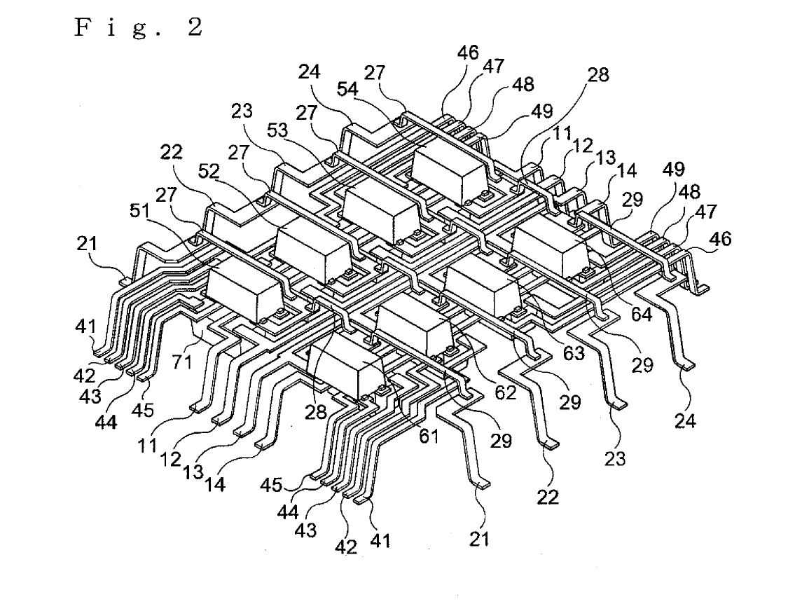

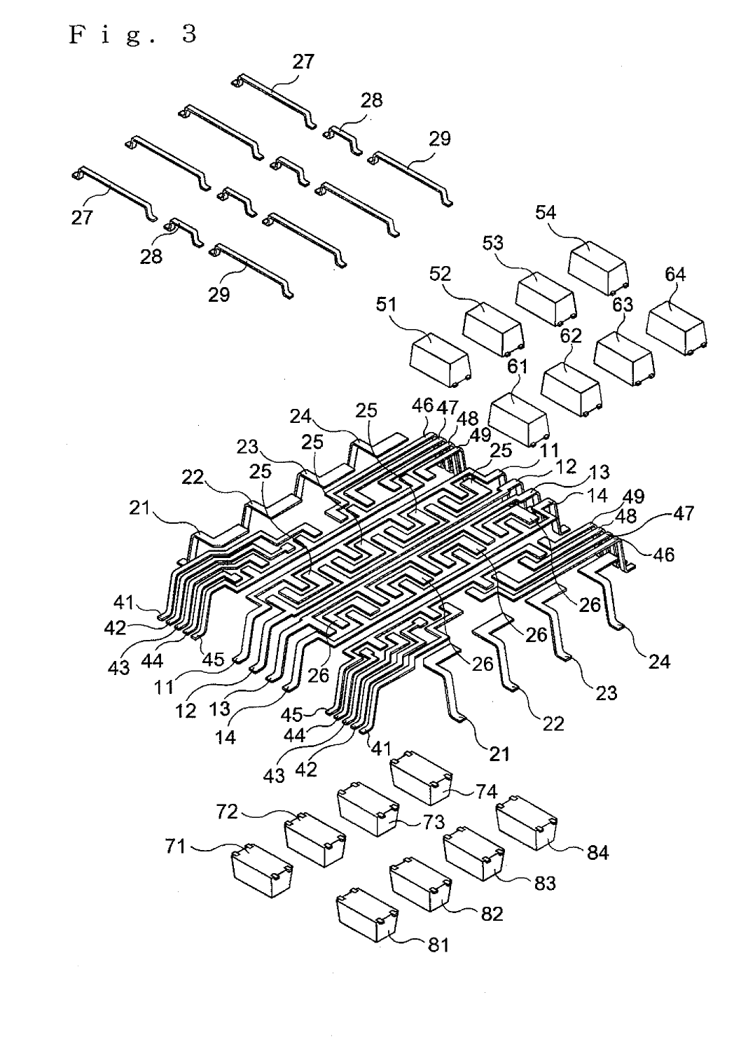

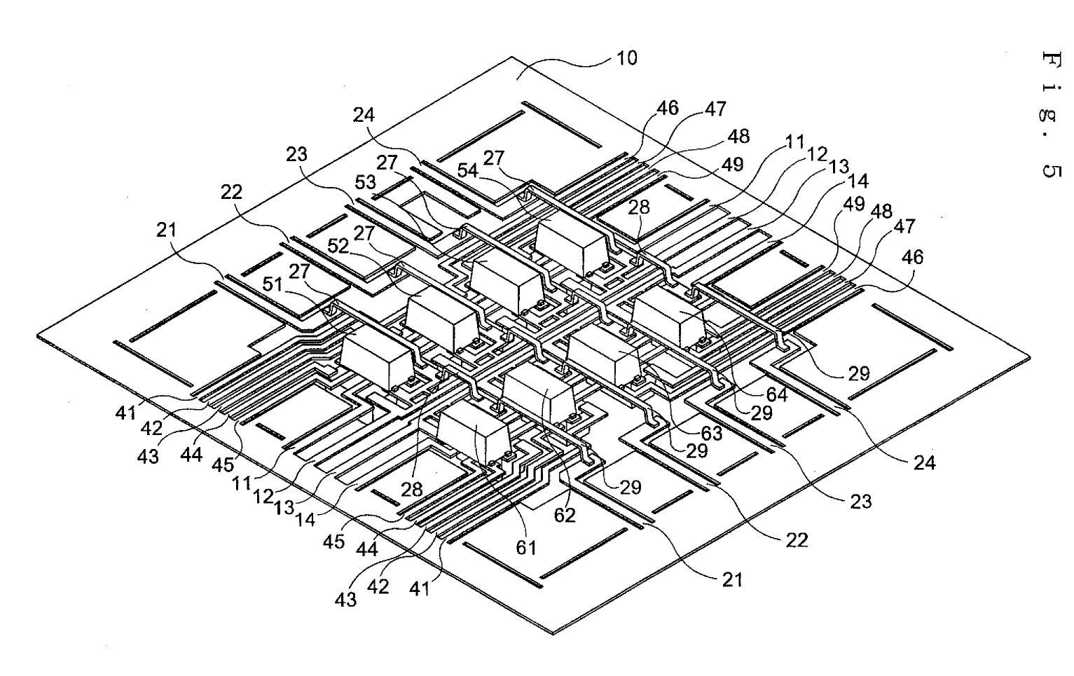

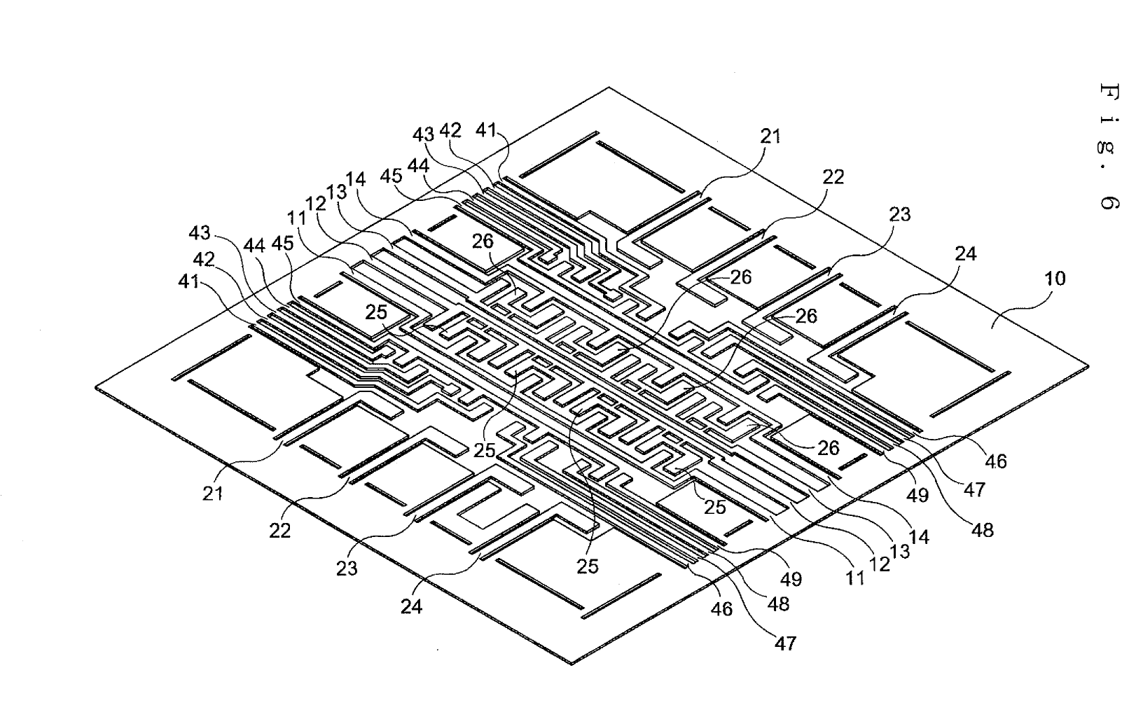

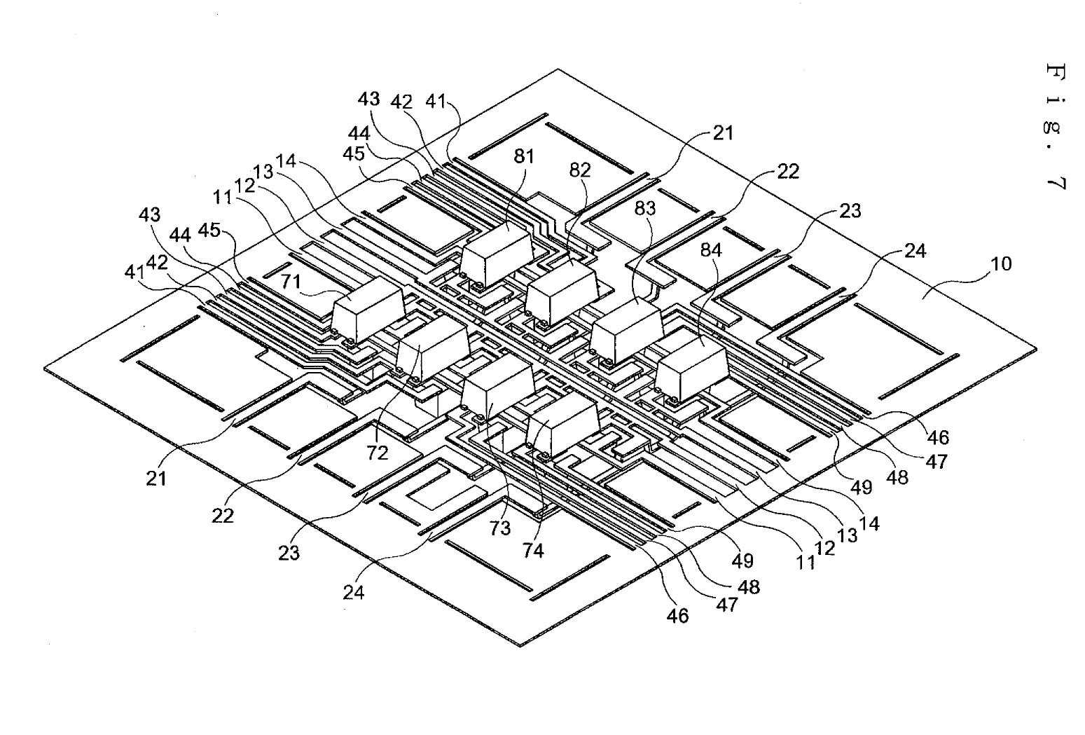

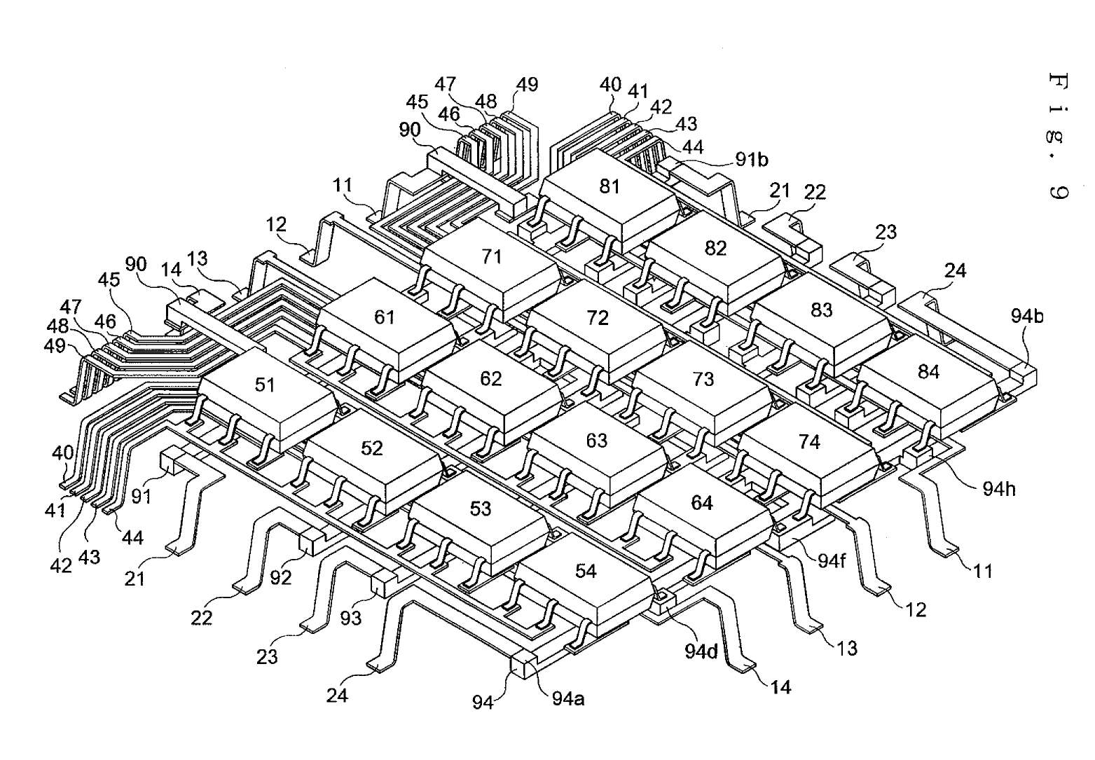

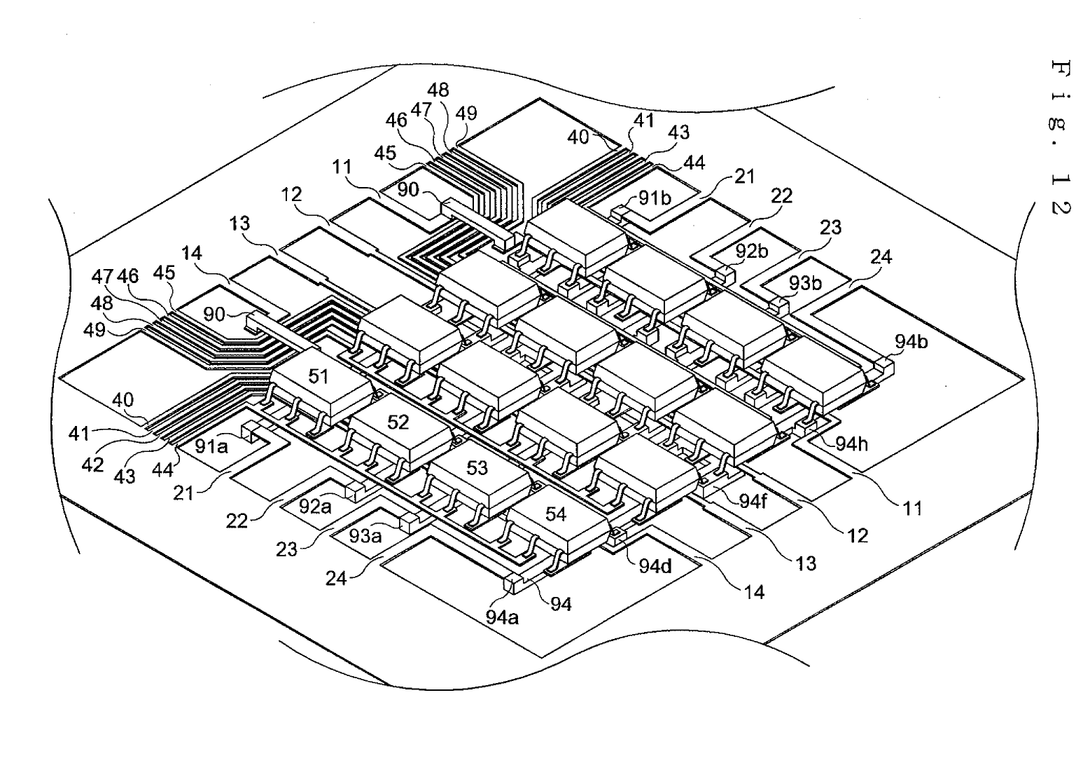

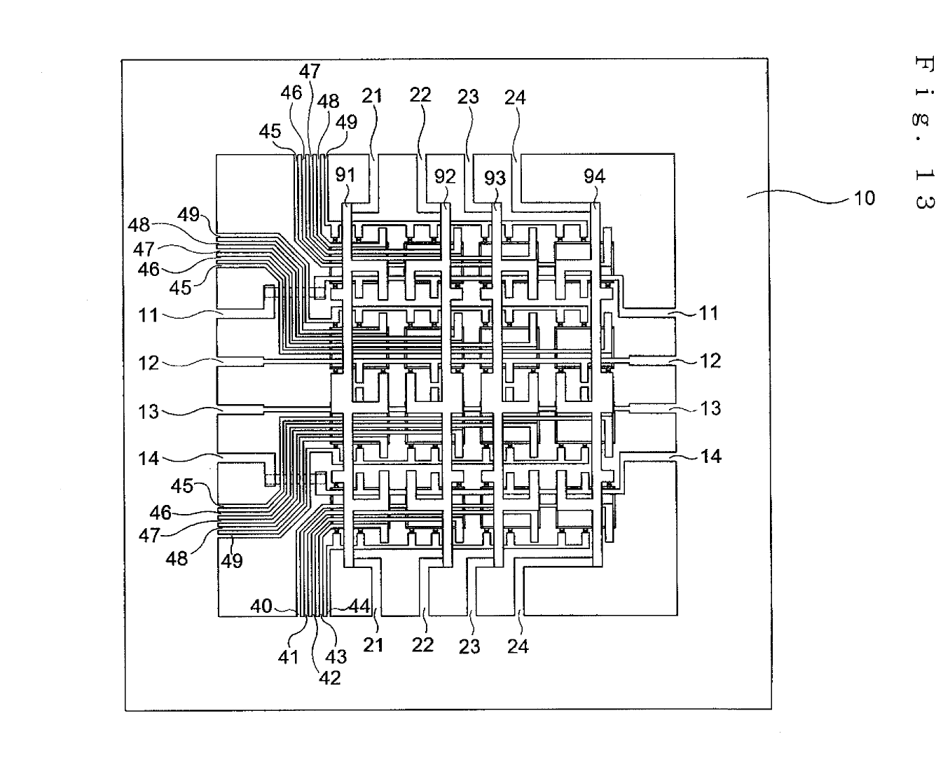

Embodiments of the present invention will be described with reference to the accompanying drawings of FIGS. 1 to 13.

As shown in FIGS. 1 to 7, a first embodiment is a matrix relay 1 wherein opening/closing elements 51-54, 61-64 are mounted on a surface of a lead frame 10, and opening/closing elements 71-74, 81-84 are mounted on a rear surface thereof, which are encapsulated with a resin.

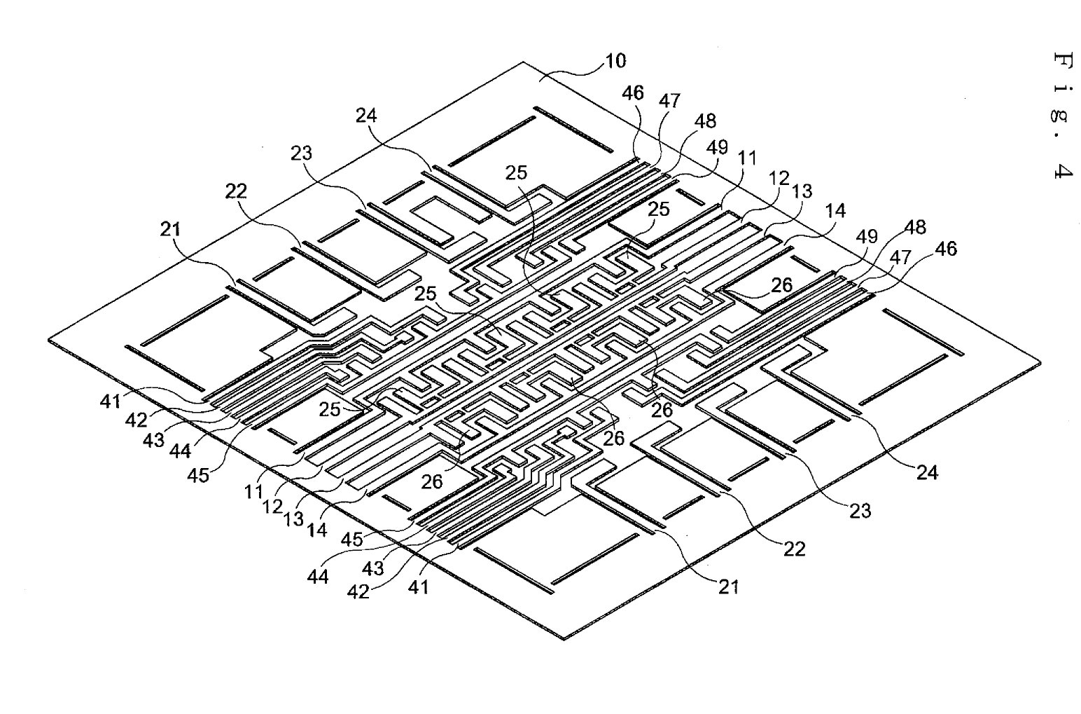

As shown in FIG. 4, the lead frame 10, which is obtained by press working a band-shaped conductive sheet, consists of row leads 11-14 for forming rows, column leads 21-24 for forming columns, and control leads 41-45, 46-49 for inputting control signals.

In the row leads 11-14, die pads are extended at a predetermined pitch in order to mount the opening/closing elements 51-54 and the like.

The column leads 21, 22, 23, 24, which are outer leads protruding from a housing 2 of the matrix relay 1, are electrically connected through relay leads 25, 26 and jumper lines 27, 28, 29, which are formed in the lead frame 10. It is a matter of course that the column leads 21-24 are insulated from the row leads 11-14 with an encapsulating resin material.

Since the relay leads 25, 26 are formed simultaneously with the row leads 11-14 and the like in the lead frame 10 by press working, there is an advantage that the number of components to be inventory-controlled does not increase.

The jumper lines 27-29, which are press working products, electrically connect the column leads 21-24 on one side serving as outer leads to the column leads 21-24 on the other side through the relay leads 25, 26.

The control leads 41-45, 46-49 are for, for example, applying voltages as control signals to the opening/closing elements 51-54 and the like described below and exciting electromagnetic coils incorporated therein, and driving movable iron pieces so that contacts are opened/closed. However, in the lead frame 10 of the present embodiment, some terminals serve as dummy terminals so as to cope with other matrix relays with different numbers of contact circuits.

It is sufficient if the opening/closing elements 51-54, 61-64, 71-74, 81-84 can open/close circuits based on the control signals, and a MOSFET, an electromagnetic relay wherein a movable iron piece is driven by an electromagnetic force to open/close a contact or an electrostatic relay wherein a movable iron piece is driven by an electrostatic attraction force to open/close a circuit is exemplified. In the present embodiment, as the opening/closing elements 51-54, 61-64, 71-74, 81-84, those elements having terminals protruding from a bottom surface and bent outward are disclosed. However, the opening/closing elements are not limited to those elements in the above embodiment, and they may have terminals protruding from side surfaces and bent to a lower side or spherical terminals protruding from the bottom surface.

Next, a method for manufacturing the matrix relay will be described.

First, as shown in FIG. 4, a cream solder is applied to predetermined positions of the surface of the lead frame 10 formed by punching through the band-shaped conductive sheet, and the jumper lines 27, 28, 29 and the opening/closing elements 51-54, 61-64 are respectively placed thereon, which are then passed through a heating furnace so as to be electrically connected.

Subsequently, the cream solder is applied to predetermined position of the rear surface of the lead frame 10, and the opening/closing elements 71-54, 81-84 are respectively placed thereon, which are then passed through the heating furnace so as to be electrically connected.

Then, after removing unnecessary connection portions for supporting the relay leads 25, 26 and the like, outer perimeter edges of the front and rear surfaces of the lead frame 10 are clamped from upper and lower sides by an integral mold not shown so that a cavity is formed. Thereafter, an encapsulation resin is injected into the cavity so as to be solidified, whereby the housing 2 is formed.

Further, the row leads 11-14, the column leads 21-24 and the control leads 41-49 that protrude from the housing 2 of the resin-encapsulated lead frame 10 are cut and bent to the lower side, whereby the matrix relay 1 shown in FIG. 1A is obtained.

According to the present embodiment, since the opening/closing elements 51-54, 61-64, and the opening/closing elements 71-74, 81-84 are placed on the front and rear surfaces of the lead frame 10, respectively, the matrix relay 1 having a small floor area and a high mounting density is obtained.

Further, in the present embodiment, the column leads 21-24 are connected through the jumper lines 27, 28, 29, whereby the order of the row leads 11-14 and the column leads 21-24 is not replaced. Therefore, an input signal terminal and an output signal terminal regularly correspond to each other. This has an advantage that it is easy to instantaneously find out a connection state and that it is easy to use.

In the present embodiment, by transmitting control signals to the control terminals 41-49 and driving the opening/closing elements 51-54, 61-64, 71-74, 81-84 so that circuits are switched over, the matrix relay 1 which is capable of outputting signals inputted to the row leads 11-14 and the column leads 21-24 from desired positions selected.

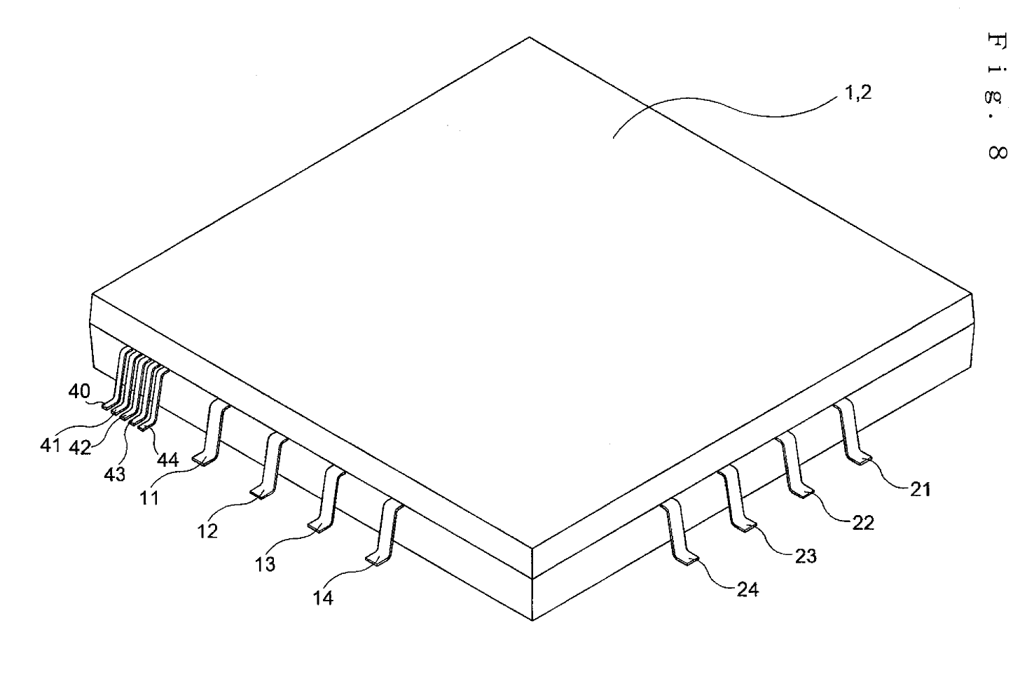

As shown in FIGS. 8 to 13, a second embodiment is a case where opening/closing elements 51-54, 61-64, 71-74, 81-84 are placed in a grid form only on a surface of a lead frame 10.

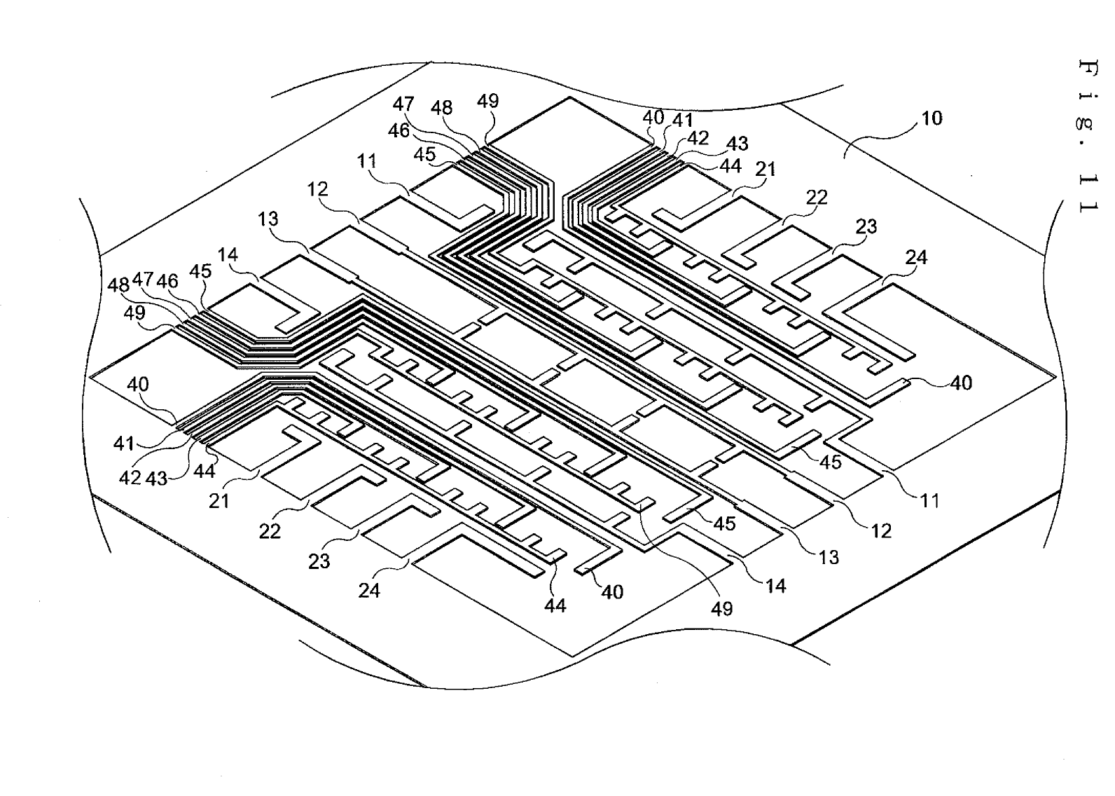

As shown in FIG. 11, the lead frame 10, which is obtained by press working a band-shaped conductive sheet, consists of row leads 11-14 for forming rows, column leads 21-24 for forming columns, and control leads 40-49 for inputting control signals.

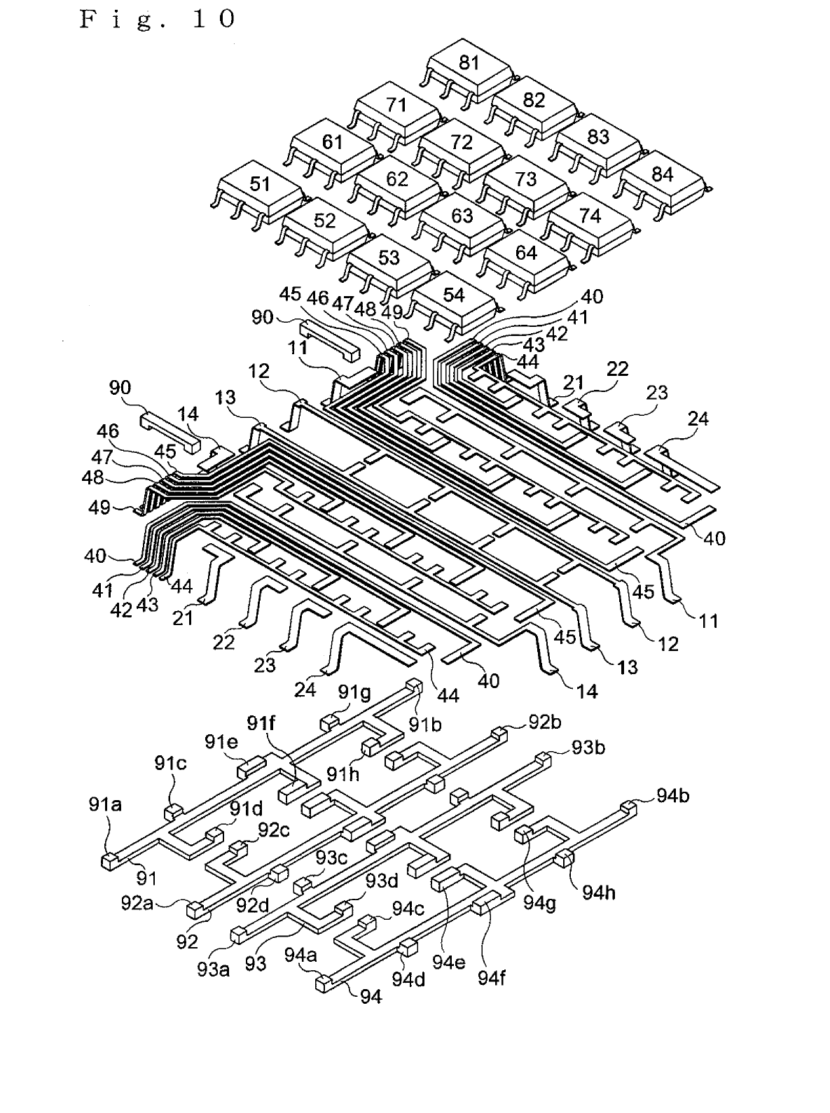

Of the row leads 11-14, the row leads 11 and 14 are electrically connected through jumper lines 90, 90 as shown in FIG. 10.

The column leads 21-24, which are outer leads protruding from a housing 2 of the matrix relay 1, are respectively electrically connected through jumper lines 91-94 described below, which are placed on a rear side of the lead frame 10. It is a matter of course that the column leads 21-24 are insulated from the row leads 11-14 with an encapsulating resin material.

The jumper lines 91-94 are each obtained by press working a bar-shaped conductive material to provide it with steps. For example, as shown in FIG. 10, die pads 94a-94h are formed on predetermined positions of the jumper line 94.

The control leads 40-44, and the control leads 45-49 are leads, for example, for applying voltages as control signals to the opening/closing elements 51-54, 61-64, 71-74, 81-84 and exciting electromagnetic coils incorporated therein, whereby movable iron pieces are driven so that contacts are opened/closed.

It is sufficient if the opening/closing elements 51-54, 61-64, 71-74, 81-84 can open/close a circuit based on control signals, and they may not necessarily be the same as those of the first embodiment.

In the present embodiment, there are six terminals in total that are protruded, each three of which terminals are protruded from each of opposite side surfaces of each of the opening/closing elements 51-54, 61-64, 71-74, 81-84. One of two terminals that are connected to the same control lead is a dummy. One of two terminals that are positioned on the opposite side and connected to the same jumper line is a dummy. This is for stabilizing mounting of the opening/closing elements and also for coping with a case where opening/closing elements of different types are mounted.

Next, a method for manufacturing the matrix relay will be described.

First, as shown in FIG. 11, a cream solder is applied to predetermined positions of the surface of the lead frame 10 formed by punching through the band-shaped conductive sheet, and the jumper lines 90, 90 are placed thereon, which are then passed through the heating furnace so as to be electrically connected. Further, the die pads provided on both end portions of the jumper lines 91-94, for example the die pads 94a, 94b of the jumper line 94 are placed level on end portions of the column leads 24, 24 and soldered to be connected. The cream solder is applied to predetermined positions of the lead frame 10, and the opening/closing elements 51-54, 61-64, 71-74, 81-84 are respectively placed thereon, which are then passed through the heating furnace so as to be electrically connected.

Subsequently, outer perimeter edges of the front and rear surfaces of the lead frame 10 are clamped from upper and lower sides by the integral mold not shown so that a cavity is formed. Thereafter, an encapsulation resin is injected into the cavity so as to be solidified, whereby the entirety is encapsulated.

Further, the row leads 11-14, the column leads 21-24 and the control leads 40-49 that protrude from the housing 2 of the resin-encapsulated lead frame 10 are cut and bent to the lower side, whereby the matrix relay 1 shown in FIG. 8A is obtained.

According to the present embodiment, since a working process of cutting unnecessary portions of the lead frame 10 is not required during the manufacturing process unlike the first embodiment, there is an advantage of being highly productive.

In the present embodiment, by transmitting control signals to the control terminals 40-49 and driving the opening/closing elements 51-54, 61-64, 71-74, 81-84 so that the circuits are switched over, the matrix relay 1 which is capable of selecting signals inputted to the row leads 11-14, the column leads 21-24 and outputting signals from desired positions is obtained.

Although the matrix relay wherein 4×4 opening/closing elements are disposed was described in the above embodiments, for example, it may be formed by disposing 1×5 opening/closing elements or disposing 3×6 opening/closing elements. It goes without saying that this may be changed as required.

### INDUSTRIAL APPLICABILITY

The matrix relay according to the present invention can be applied not only to the above embodiments but also to other forms of matrix relays.

1. A matrix relay wherein row leads of a lead frame, which are wired so that a plurality of input terminals and a plurality of output terminals are disposed respectively at opposite both sides, column leads of the lead frame, which are wired so that a plurality of input terminals and a plurality of output terminals are disposed respectively at both sides adjacent both the opposite sides, and a plurality of opening/closing elements, which are respectively connected to the row leads and the column leads, are encapsulated with a resin in a square housing; wherein
at least one of the row leads and the column leads is formed through at least one jumper line.

2. The matrix relay according to claim 1, wherein an intermediate region of each of the row leads or each of the column leads is formed of a relay lead disposed in the lead frame and the jumper line.

3. The matrix relay according to claim 1, wherein the jumper line is obtained by providing a bar-shaped conductive wire with steps on each of which a die pad is provided protrusively.

4. The matrix relay according to claim 2, wherein the jumper line is obtained by providing a bar-shaped conductive wire with steps on each of which a die pad is provided protrusively.
